(19) United States
(12) Patent Application Publication
(10) Pub. No.: US 2011/0222223 A1
(43) Pub. Date: Sep. 15, 2011

(54) FOLDING PORTABLE ELECTRONIC DEVICE

(75) Inventors: Kenichi Mochizuki, Kanagawa (JP); Takashi Ishihara, Kanagawa (JP)

(73) Assignee: PANASONIC CORPORATION, Osaka (JP)

(21) Appl. No.: 13/131,495

(22) PCT Filed: Jun. 15, 2009
(86) PCT No.: PCT/JP2009/002713

§ 371 Date: May 26, 2011

(30) Foreign Application Priority Data
Dec. 1, 2008 (JP) 2008-306114

(51) Int. Cl. H05K 5/02

(52) U.S. Cl. 361/679.01

(57) ABSTRACT

To solve the problem that the user's finger may be pinched and prevent the deterioration of the operability on the one-push portion in a structure in which at least either of outer hinge members is rotated relative to a second housing provided with a main operation section. In a folding portable electronic device, a hinge section 13 has a structure in which a rotational section 13a is rotated along with a first housing 11 about a rotational axis when the first housing 11 is opened relative to a second housing 12, a part of the rotational section 13a of the hinge section 13 is disposed to be located outwardly at least either of side end portions of the first housing 11, and the rotational axis of the hinge section 13 is, in both open and closed states of the housings, located on a line extended from the base end portion of the hinge section side of the second housing 12. A push button 20 is provided on the second housing 12. A convex portion 30 or a projection portion 32 is formed on the side opposite to the push button 20.

### TECHNICAL FIELD

The present invention relates to a folding portable electronic device provided with a hinge section which couples housings so as to be opened and closed.

### BACKGROUND ART

In the past, there has been a folding portable electronic device having a housing structure which opens and closes by a hinge section as a portable electronic device such as a cellular phone. In this kind of the portable electronic device, it is general to adopt a structure which includes a first housing provided with a main display section, a second housing provided with a main operation section, and a hinge section which rotatably couples the first housing to the second housing, and in which the two housings are opened and closed in accordance with the rotation of the hinge section.

In the folding portable electronic device, when the second housing provided with the main operation section to be gripped and operated by a user is considered as basis, the structure of the hinge section includes one in which only an inner hinge member is rotated and opposite outer hinge members are fixed (the opposite outer hinge members are integrally formed with the second housing) during opening and closing the housings; and the other one in which either or both of the opposite hinge members are rotated (either or both of the opposite hinge members are integrally formed with the first housing). When the user grips the second housing, and open or close the housings, in the case of the structure in which at least either of the outer hinge members is rotated, the user's finger may be pinched between the hinge member which is rotated when the housings are opened and the second housing.

As an example of the structure in which either of the outer hinge members are rotated relative to the second housing provided with the main operation section, Patent Literature 1 (JP-A-2008-187285) discloses a folding portable terminal device in which a rib is provided outside a side surface of the second housing.

### CITATION LIST

### Patent Literature

Patent Literature 1: JP-A-2008-187285 (FIG. 1)

### SUMMARY OF INVENTION

### Technical Problem

Patent Literature 1 adopts the structure in which the rib is provided to simplify the opening operation, but does not consider the problem that the user's finger may be pinched and disturb the rotation of the housings when the housings are opened.

Further, in order to enhance the operability of the opening and closing operation, recently there is a folding portable electronic device in which a one-push portion (a one-push button) is provided on a side surface of either of the housings, and the first housing is opened in accordance with the pressing operation of the button. However, in the case of providing the one-push button in the folding portable terminal device described in Patent Literature 1, when the user presses the button with one finger (normally with the thumb), the side surface opposite to the button is also rotated. Then, a force opposite to a direction for pressing the button is applied by the other finger of the user (normally by the index finger). In this case, the force to open the first housing is lost, and the operability is deteriorated.

The present invention has been made in view of the above circumstance, and aims at providing a folding portable electronic device capable of solving the problem that the user's finger may be pinched and also preventing the deterioration of the operability on the one-push portion in a structure in which at least either of outer hinge members is rotated relative to a second housing provided with a main operation section, and the one-push portion is provided.

### Solution to Problem

The present invention provides a folding portable electronic device, including: a first housing which is provided with a main display section; a second housing which is provided with a main operation section; and a hinge section which couples the first housing to the second housing so as to be opened and closed, wherein the hinge section includes a one-push portion which automatically opens the first housing and the second housing by pressing the one-push portion, and a rotational section which includes at least an opposite-end portion which is located on an opposite side to the one-push portion in a lateral direction of the first housing, the rotational section is rotated along with the first housing around a rotational axis when the first housing is opened relative to the second housing, and a convex portion is formed to be projected from the first housing in the lateral direction on a surface of the opposite-end portion and in the rotational axis.

According to the configuration, the user can press the one-push portion while holding the convex portion in a structure in which at least either of outer hinge members is rotated relative to the second housing provided with the main operation section. Accordingly, it is possible to suppress the deterioration of the operability for opening the housings even if the rotational section opposite to the one-push portion is rotated.

The present invention includes the configuration in which the convex portion is formed of a part of a member which can be rotated independently of the first housing.

According to the configuration, it is possible to improve the operability for opening the housings.

The present invention also provides a folding portable electronic device, including: a first housing which is provided with a main display section; a second housing which is provided with a main operation section; and a hinge section which couples the first housing to the second housing so as to be opened and closed, wherein the hinge section includes a one-push portion which automatically opens the first housing and the second housing by pressing the one-push portion, and a rotational section which includes at least an opposite-end portion which is located on an opposite side to the one-push portion in a lateral direction of the first housing, the rotational section is rotated along with the first housing around a rotational axis when the first housing is opened relative to the second housing, and a projection is formed to be projected from the second housing toward the hinge section in a region at least including the rotational axis on an opposite side to the one-push portion in a lateral direction of the second housing.

According to the configuration, the user can press the one-push portion while holding the projection portion in a structure in which at least either of outer hinge members is rotated relative to the second housing provided with the main operation section. Accordingly, it is possible to suppress the deterioration of the operability for opening the housings even if the rotational section opposite to the one-push portion is rotated.

The present invention includes the configuration in which the projection is projected also in the lateral direction from the second housing.

### Advantageous Effects of Invention

The present invention can provide a folding portable electronic device capable of solving the problem that the user's finger may be pinched and also preventing the deterioration of the operability on the one-push portion in a structure in which at least either of outer hinge members is rotated relative to a second housing provided with a main operation section.

### BRIEF DESCRIPTION OF DRAWINGS

FIG. 1 is perspective views, each showing an outer appearance of a folding portable electronic device according to an embodiment of the invention.

FIG. 2 is side views of the folding portable electronic device according to the embodiment.

FIG. 3 is a front view of the folding portable electronic device in the vicinity of a hinge section.

FIG. 4 is a perspective view of the folding portable electronic device in the vicinity of the hinge section.

FIG. 5 is perspective views showing an operation of opening the folding portable electronic device.

FIG. 6 is a diagram showing modified examples of a convex portion.

FIG. 7 is a diagram showing a rotational member constituting the convex portion, in which (a) is a front view showing the relation with a housing; and (b) is a perspective view of a single piece of the rotational member.

FIG. 8 is a diagram showing another example of the rotational member constituting the convex portion.

FIG. 9 shows a folding portable electronic device according to another embodiment, in which (a) is a front view in the vicinity of the hinge section; and (b) is a perspective view in the vicinity of the hinge section.

FIG. 10 is a perspective view of the folding portable electronic device in the vicinity of the hinge section according to the other embodiment.

### DESCRIPTION OF EMBODIMENTS

An embodiment as mentioned below shows a configurative example of a folding portable electronic device when the present invention is applied to a portable terminal device such as a cellular phone. The present invention can be applied to various portable electronic devices which are held by a user.

### Embodiment

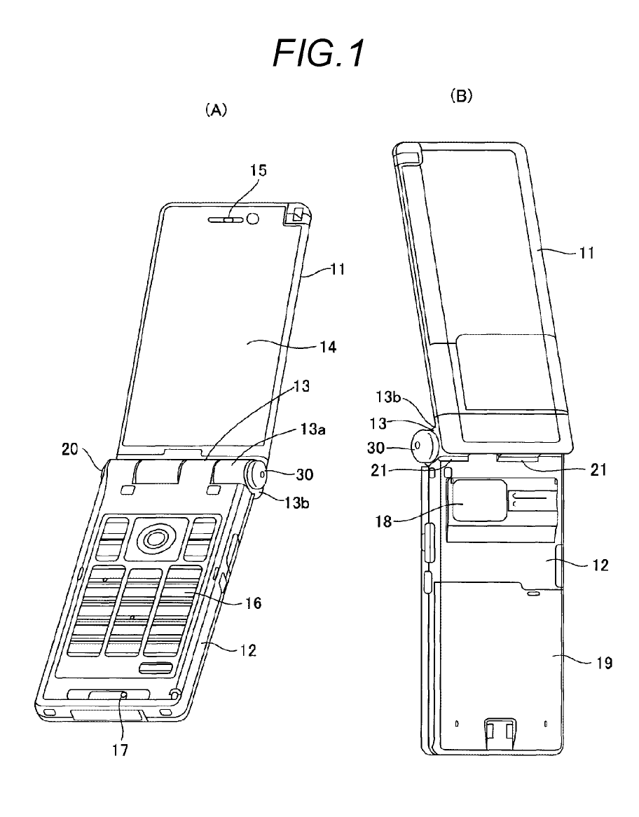

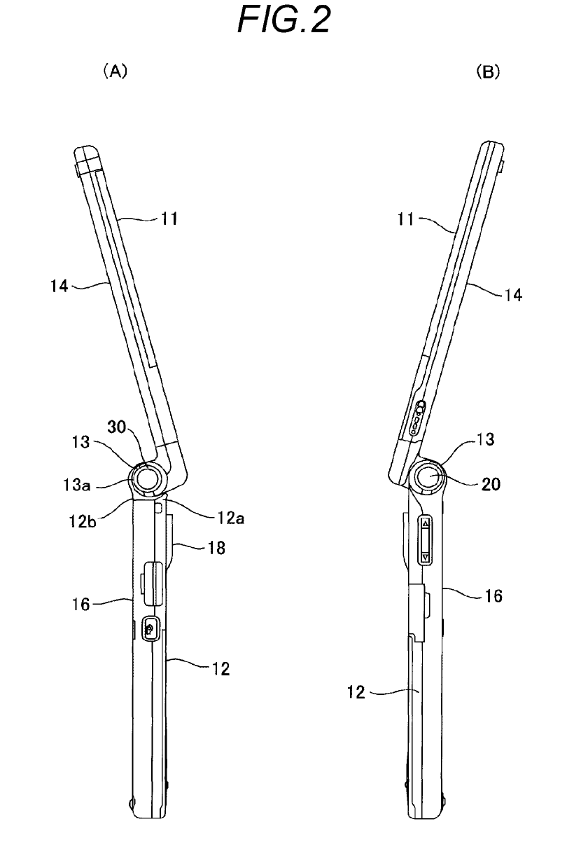

FIG. 1 is perspective views, each showing an outer appearance of a folding portable electronic device according to an embodiment of the invention. In FIG. 1, (A) is a perspective view as viewed from a front side on which a display section and an operation section are arranged in an opened state of housings. In FIG. 1, (B) is a perspective view as viewed from a rear side in the opened state of the housings. FIG. 2 is side views of the folding portable electronic device according to the embodiment. In FIG. 2, (A) is a diagram showing one side surface in the opened state of the housings. In FIG. 2, (B) is a diagram showing the other side surface in the opened state of the housings.

The portable electronic device according to the embodiment includes a first housing 11 and a second housing 12 which have a thin substantially-cubic shape or a plate shape. The portable electronic device has a folding structure in which an end of the first housing 11 is rotatably coupled to an end of the second housing 12 by a hinge section 13. The portable electronic device can be in a closed state or an opened state by opening or closing the housings in accordance with a rotation around a rotational axis of the hinge section 13.

The first housing 11 is provided with a display section 14 as a main display section and a receiver 15 which outputs a talking voice in a telephone function on a front side (hereinafter, this side is referred to as a first surface) which is an inner side in the closed state of the housings. The display section 14 includes a display device such as an LCD or an organic EL display, and displays an operating state of the device, respective functions display, a menu display or a standby display on a display screen.

The second housing 12 is provided with an operation section 16 as a main operation section and a microphone 17 to which a talking voice is input in a telephone function on the first surface which is the inner side in the closed state of the housings. The operation section 16 includes an operation input device such as a plurality of push buttons of numeric keypad or four-way operation keys, and is provided for operation inputs corresponding to the various operations by the user. Further, the second housing 12 is provided with a camera unit 18 and a battery pack 19 on a rear side (hereinafter, this side is referred to as a second surface) which is an outer side in the closed state of the housings.

The hinge section 13 is split into four sections as viewed from the front side. In (A) of FIG. 1, the member on the right end side and the third member from the right end are integrally formed with the first housing 11, and the second member from the right end and the member on the left end side are integrally formed with the second housing 12. Accordingly, when the user grips the second housing 12 and opens or closes the housings, since the first housing 11 is rotated relative to the second housing 12, the member on the right end side and the third member from the right end in (A) of FIG. 1 serving as a hinge rotational section are rotated along with the first housing 11. That is, a part of a rotational section of the hinge section 13 is disposed at an end in a lateral direction of the first housing 11, and is located outwardly in at least one of right and left side end portions. In (A) of FIG. 1, the left side end portion of the hinge section 13 is provided with a push button 20 to be operated when user is to open the housings. The hinge section 13 has so-called one-push open mechanism (one-push portion), and comes into the opened state by a depression operation (pressing) of the push button 20 so that the two housings are rotated in an opening direction for themselves due to the force by a spring or the like. The push button 20 is disposed at an end in a longitudinal direction of the second housing 12.

As mentioned above, the hinge section 13 according to the embodiment adopts a structure in which a rotational section 13a at one outer side is rotated relative to the second housing 12. In this case, the structure can be adopted in which rotational sections of the hinge section at both outer sides are rotated relative to the second housing 12 instead of providing it at the one outer side. The hinge section 13 is located on an extension line of a side surface in the longitudinal direction of the second housing, i.e., of a base end part of the second housing 12 at the hinge section side both in states where the shaft center of the rotational axis is opened and closed. That is, a base end part of the first housing 11 at the hinge section side is configured to be opened to be projected more outwardly than an extending surface in the longitudinal direction of the second surface of the second housing 12.

In such a hinge structure, the base end part 12a of the second housing 12 adjoining the hinge section 13 is configured so that an end surface 12b, facing the outer rotational section 13a of the hinge section 13 which is formed by cutting a part of a cylinder, is formed along a rotational locus of the rotational section 13a, and is formed in a concave arc-like shape along an outer shape of a circle of the rotational section 13a. The portion which the rotational section 13a of the hinge section 13 faces the base end part 12a of the second housing 12, i.e., the outer shape of the circle in a cylindrical shape of the rotational section 13a and the arc shape of the end surface 12b of the based end part 12a corresponding to the outer shape may be in the ellipsoidal shape as shown in the figure or in a precise circle. In this case, the end surface 12b of the second housing 12 is configured to form a curved surface for securing a predetermined clearance while being brought close as much as possible with respect to the outermost locus which the rotational part 13a of the hinge section 13 creates in rotation. According to the structure, the end surface 12b of the base end part 12 of the second housing 12 is located closely at all times during the rotation of the hinge section 13. Thus, the user's finger, etc. is prevented from being pinched between the rotational section 13a of the hinge section 13 and the base end part 12a of the second housing 12 when the housings are opened.

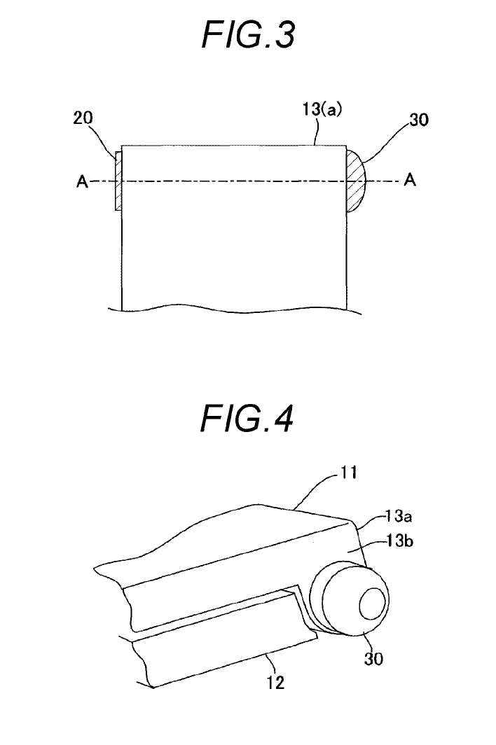

An end portion located on an opposite side of the push button 20 in the lateral direction of the first housing 11 along the rotational axis of the hinge section is defined as an opposite-end portion 13b. The rotational section 13a includes the opposite-end portion 13b. As shown in FIG. 3 and FIG. 4, a convex portion 30 is formed to be projected in the lateral direction of the housing from the first housing 11 on a surface of the opposite-end portion 13b. The convex portion 30 is formed in the rotational axis A on the surface of the opposite-end portion 13b.

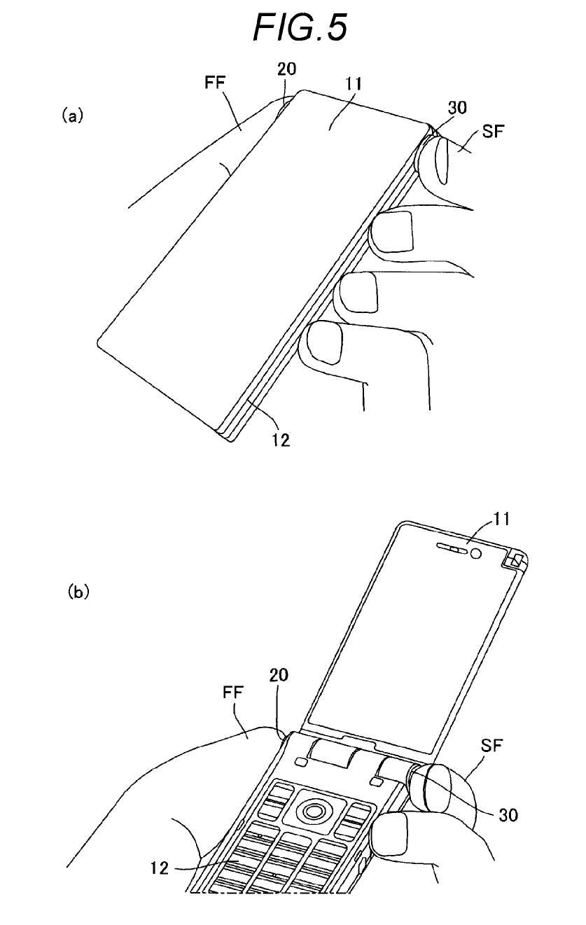

As shown in (a) of FIG. 5, when opening the folding portable electronic device, the user presses the push button 20 with his/her thumb FF in a general way. As shown in (b) of FIG. 5, the rotational section 13a of the first housing is also rotated when the first housing 11 is opened. In general, a force opposite to the direction of pressing the push button 20 is applied to the side surface of the rotational section 13a with the user's index finger SF.

In the general folding portable electronic device, the force for opening the first housing is lost due to the force from the index finger SF, thereby deteriorating the operability. However, the folding portable electronic device according to the invention is provided with the convex portion 30, and thus, the user's index finger SF is put on the convex portion 30. Since the contact area between the index finger SF and the convex portion 30 is small, the friction to be occurred is also small. Thus, even in the rotation of the first housing and the rotational section 13a, the friction between the rotational section 13a and the index finger SF can be suppressed, and the first housing 11 can be opened smoothly.

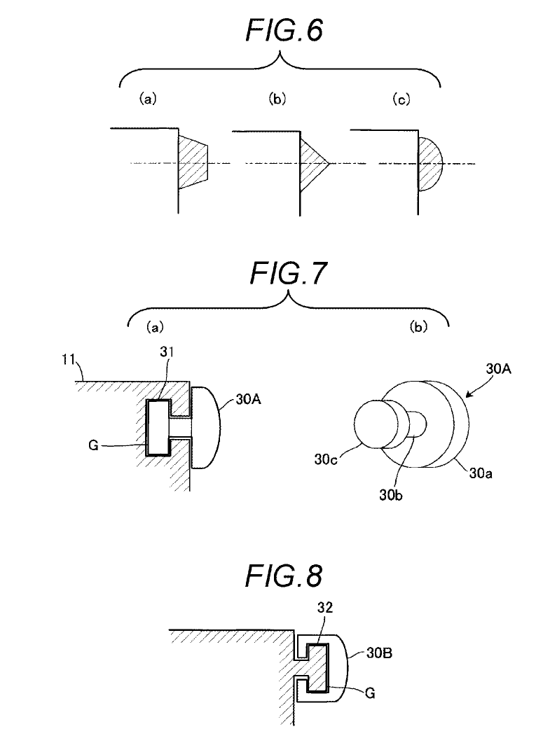

In the example of FIG. 1 through FIG. 5, the convex portion 30 is made in a flat-plate shape. However, the shape of the convex portion 30 is not limited particularly, and various shapes such as a trapezoidal shape as shown in (a) of FIG. 6, a triangular pyramid shape as shown in (b) of FIG. 6, and a semispherical shape as shown in (c) of FIG. 6 can be adopted as the shape of the convex portion 30.

In the above example, the convex portion 30 is integrally formed with the first housing 11. However, the convex portion 30 can be formed of a separate member independently of the first housing 11. FIG. 7 shows a rotational member 30A constituting the convex portion 30. The rotational member 30A constitutes the convex portion 30 by a part of the rotational member 30A being a large diameter part 30a which is exposed outwardly. Further, the rotational member 30A includes a middle diameter part 30c and a small diameter part 30b connecting the large diameter part 30a and the middle diameter part 30c. The middle diameter part 30 and the small diameter part 30b are incorporated into a concave section 31 formed in the first housing 11 while securing a gap G. Accordingly, the rotational member 30A can be rotated independently even in the rotation of the first housing 11.

In the situation of FIG. 5, when the rotational member 30A is held with the index finger SF, the rotational member 30A is not rotated while holding it with the index finger SF even if the first housing 11 is rotated. In other words, the rotational member 30A is rotated relatively with respect to the first housing 11. According to the structure, the rotation of the first housing 11 is performed smoothly, thereby improving the operability to open the housings.

FIG. 8 shows a rotational member 30B as a modified example of the rotational member 30A in FIG. 7. The rotational member 30B is rotatably attached to a projection 32 which is provided on the first housing 11 while securing a gap G. The same effect as in the configuration of FIG. 7 can be obtained by this example.

FIG. 9 shows a main part of a folding portable electronic device according to another embodiment of the invention. In this embodiment, a projection portion 32 is provided on a side surface of the second housing 12 instead of providing the convex portion 30 on the first housing 11. The projection portion 32 is provided in a region at least including the rotational axis A on an opposite side to the one-push button 20 in the lateral direction of the second housing 12. The projection portion 32 is projected from an end of the second housing 12 as indicated by a dot-line B toward the hinge section 13. The projection portion 32 is projected also in the lateral direction of the housing from the second housing 12.

In the embodiment, when the first housing 1 is opened, the user's index finger SF is put on the projection portion 32. Since the index finger SF is prevented from directly contacting the first housing 11 and the rotational section 13a, the first housing 11 is opened smoothly.

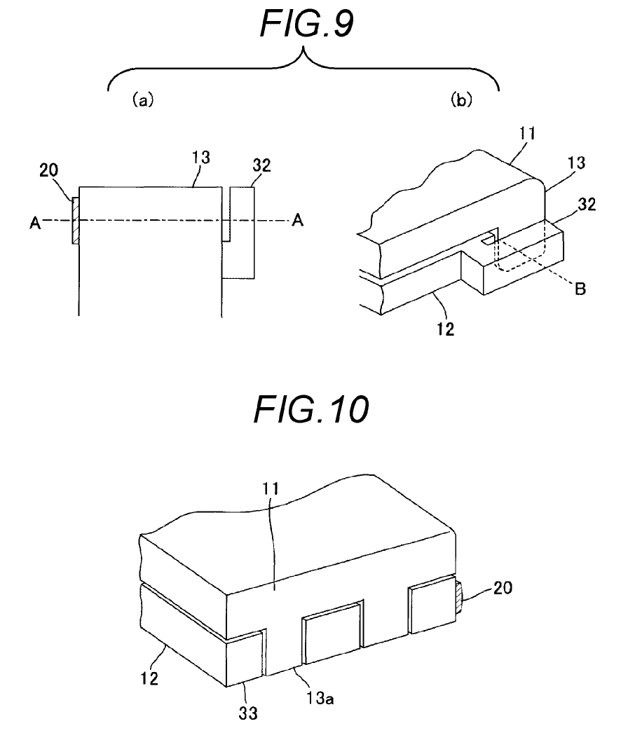

FIG. 10 shows a modified example of FIG. 9. In this example, unlike the projection portion 32, a projection portion 33 is not projected in the lateral direction of the housing from the second housing 12. Even by this example, the smooth operability is secured, and also the design is favorable because the projection portion from the housing is eliminated.

The present invention is not limited to the configuration shown in the embodiments as mentioned above. The present invention assumes the modification and the application by the person skilled in the art on the basis of the description of the specification and the common art, and they are included in the scope of the invention to be protected.

This application is based upon Japanese Patent Application No. 2008-306114 filed on Dec. 1, 2008, the contents of which are incorporated herein by reference.

### INDUSTRIAL APPLICABILITY

The present invention is capable of solving the problem that the user's finger may be pinched and also preventing the deterioration of the operability on the one-push portion in a structure in which at least either of outer hinge members is rotated relative to a second housing provided with a main operation section. The present invention can be applied to the portable terminal device such as a cellular phone, and is useful for a folding portable electronic device provided with a hinge section which rotatably couples the housings.

### REFERENCE SIGNS LIST

11: first housing
12: second housing
12a: base end part
12b: end surface
13: hinge section
13a: rotational section
14: display section
16: operation section
18: camera unit
20: push button
30: convex portion
32, 33: projection portion

1. A folding portable electronic device, comprising:
a first housing which is provided with a main display section;
a second housing which is provided with a main operation section; and
a hinge section which couples the first housing to the second housing so as to be opened and closed, wherein
the hinge section includes a one-push portion which automatically opens the first housing and the second housing by pressing the one-push portion, and a rotational section which includes at least an opposite-end portion which is located on an opposite side to the one-push portion in a lateral direction of the first housing,
an end of the first housing which is coupled to the hinge section is projected more outwardly than a surface opposite to a surface which is provided with the main operation section of the second housing when the first housing is opened relative to the second housing,
the rotational section is rotated along with the first housing around a rotational axis when the first housing is opened relative to the second housing, and
a convex portion is formed to be projected from the first housing in the lateral direction on a surface of the opposite-end portion and in the rotational axis.

2. The folding portable electronic device according to claim 1, wherein
the convex portion is formed of a part of a member which can be rotated independently of the first housing.

3. A folding portable electronic device, comprising:
a first housing which is provided with a main display section;
a second housing which is provided with a main operation section; and
a hinge section which couples the first housing to the second housing so as to be opened and closed, wherein
the hinge section includes a one-push portion which automatically opens the first housing and the second housing by pressing the one-push portion, and a rotational section which includes at least an opposite-end portion which is located on an opposite side to the one-push portion in a lateral direction of the first housing,
an end of the first housing which is coupled to the hinge section is projected more outwardly than a surface opposite to a surface which is provided with the main operation section of the second housing when the first housing is opened relative to the second housing,
the rotational section is rotated along with the first housing around a rotational axis when the first housing is opened relative to the second housing, and
a projection is formed to be projected from the second housing toward the hinge section in a region at least including the rotational axis on an opposite side to the one-push portion in a lateral direction of the second housing.

4. The folding portable electronic device according to claim 3, wherein
the projection is projected also in the lateral direction from the second housing.
